(19) United States
(12) Patent Application Publication
(10) Pub. No.: US 2026/0164574 A1
(43) Pub. Date: Jun. 11, 2026

(54) Compatible Display Mechanism

(71) Applicant: SHENZHEN GLOSHINE TECHNOLOGY CO., LTD., Shenzhen (CN)

(72) Inventors: Xianfeng Zhang, Shenzhen (CN); Guoqiang Li, Shenzhen (CN); Yongfeng Guo, Shenzhen (CN); Xinyong Chen, Shenzhen (CN)

(21) Appl. No.: 19/240,229

(22) Filed: Jun. 17, 2025

Related U.S. Application Data
(63) Continuation of application No. PCT/CN2025/087047, filed on Apr. 3, 2025.

(30) Foreign Application Priority Data
Dec. 6, 2024 (CN) 202423012735.4

(51) Int. Cl. H05K 5/02

(52) U.S. Cl. CPC H05K 5/0221

(57) ABSTRACT

Provided is a compatible display mechanism, including a display screen mechanism, a support assembly, and a support frame connected to a side surface of the display screen mechanism; the support assembly includes a plurality of corner support blocks having different thicknesses; and a corner mounting groove is provided at a corner of the display screen mechanism, and the corner support block corresponding to the support frame is mounted in the corner mounting groove; a side surface of the support frame abuts against the side surface of the display screen mechanism and the corner support block, such that the support frame is adapted to the display screen mechanism and the corner support block. Corner support blocks with different thicknesses are selected based on the display screen mechanism and/or support frame thickness, ensuring the support frame side thickness equals the sum of the box body corner and block thickness, providing stable mounting.

### CROSS REFERENCE TO RELATED APPLICATIONS

The present application is a Continuation Application of PCT Application No. PCT/CN2025/087047 filed on Apr. 3, 2025, which claims priority to Chinese Patent Application No. 202423012735.4, filed on Dec. 6, 2024, entitled “Compatible Display Mechanism”, the contents of which are incorporated herein by reference in their entirety.

### TECHNICAL FIELD

The present application relates to the field of display screen technology, and in particular, to a compatible display mechanism.

### BACKGROUND

With ongoing technological advancements, display screens are increasingly used in daily life for presenting advertisements, promotional animations, and other content. To stimulate consumers'desire to shop, many display screens are also installed in shopping malls. Typically, display screens are mounted using support frames. To ensure stable mounting, each display screen is correspondingly paired with a support frame. However, when replacing a display screen of a different thickness, the support frame must also be replaced accordingly, resulting in high replacement costs and inconvenient operation.

### SUMMARY OF THE DISCLOSURE

To address the technical problems of high replacement costs and inconvenient operation between the display screen and the support frame in the prior art, the present application provides a compatible display mechanism.

In view of the above technical problem, an embodiment of the present application provides a compatible display mechanism, which include: a display screen mechanism, a support assembly, and a support frame connected to a side surface of the display screen mechanism; the support assembly includes a plurality of corner support blocks having different thicknesses; and
a corner mounting groove is provided at a corner of the display screen mechanism, and the corner support block corresponding to the support frame is mounted in the corner mounting groove; a side surface of the support frame abuts against the side surface of the display screen mechanism and the corner support block, such that the support frame is adapted to the display screen mechanism and the corner support block.

Optionally, the corner support block includes a corner block and two side plates each connected to the corner block, and a mounting groove is provided between each side plate and the corner block; and
the corner block is mounted in the corner mounting groove, the two side plates are respectively aligned with two adjacent side edges of the display screen mechanism, and the side surface of the support frame abuts against the side surface of the display screen mechanism and the side plates.

Optionally, the display screen mechanism includes a box body and a plurality of display modules mounted on the box body, and the corner mounting groove is arranged at a corner of the box body on an end away from the display module;
the corner support block corresponding to the support frame is mounted in the corner mounting groove, and the side surface of the support frame abuts against a side surface of the box body and the corner support block, such that the support frame is adapted to the box body and the corner support block; and
the display screen mechanism further includes a plurality of status indicators mounted on the display modules in a one-to-one correspondence.

Optionally, the status indicator includes an indicator plate and an actuating tab connected to the indicator plate, and the indicator plate is provided with a first indicator part and a second indicator part located on opposite sides of the actuating tab;
the display module is provided with an internal space and a window communicating with the internal space, the indicator plate is slidably mounted in the internal space, and an end of the actuating tab away from the indicator plate protrudes from the window; and
the actuating tab is configured to drive the indicator plate to slide in the internal space, such that the window displays the first indicator part or the second indicator part.

Optionally, opposite ends of the box body are respectively provided with a first groove and a second groove in communication with the first groove, the display module is configured to cover the first groove, and the corner mounting groove is arranged at a corner of the second groove;
the display screen mechanism further includes a battery assembly, a knob provided with a rotating latch, and a support frame provided with a rotating groove; the knob is rotatably mounted on the battery assembly, the support frame is mounted on the box body and located in the second groove, and the battery assembly is mounted in the second groove by the rotating latch locked into the rotating groove.

Optionally, the box body is further provided with a first fastening hole in communication with the first groove, and the support frame is provided with a second fastening hole; and
the support frame is mounted on the box body by a fastener inserted into the first fastening hole and the second fastening hole.

Optionally, the box body includes a frame and a first support arm and a second support arm spaced apart and connected to the frame, the first groove and the second groove are respectively arranged at opposite ends of the frame; and
the first support arm and the second support arm each are provided with the first fastening hole; the battery assembly is mounted on the first support arm and the second support arm by the support frame.

Optionally, the display screen mechanism further includes a protection plate and a latching member, and the protection plate is detachably mounted on the side surface of the box body by the latching member.

Optionally, the latching member includes a latching body and a latching hook connected to the latching body, a side of the box body is provided with a latching groove adapted to the latching hook, and the protection plate is provided with a third groove adapted to the latching body; and
the latching body is mounted on the box body by the latching hook engaged in the latching groove, and the protection plate is mounted on the side surface of the box body by the latching body inserted into the third groove.

Optionally, the latching member further includes a first elastic arm and a second elastic arm connected to opposite sides of the latching body, and opposite inner sidewalls of the third groove are respectively provided with a first protruding hook and a second protruding hook; and
when the latching body is inserted into the third groove, the first protruding hook abuts against the first elastic arm, and the second protruding hook abuts against the second elastic arm.

In this application, the support assembly includes a plurality of corner support blocks with different thicknesses. A corner mounting groove is provided at a corner of the display screen mechanism, and the corner support block corresponding to the support frame is mounted in the corner mounting groove. When the display screen mechanism or the support frame needs to be replaced, a suitable corner support block can be selected based on the support frame and the display screen mechanism. In this way, when the support frame is mounted on the side surface of the display screen mechanism, the side surface of the support frame abuts against the side surface of the display screen mechanism and the corner support block. In this application, corner support blocks of varying thicknesses can be selected based on the thickness of the display screen mechanism and/or the support frame. This allows the thickness of the side surface of the support frame to equal the sum of the thickness of the side surface at the corner of the box body and the thickness of the corner support block, thereby ensuring the stable mounting of the display screen mechanism onto the support frame. Moreover, there is no need to replace both the display screen mechanism and the support frame simultaneously. By selecting a corner support block with a matching thickness, the display screen mechanism can be stably mounted onto the support frame, thereby reducing replacement costs and simplifying the replacement process of the compatible display mechanism.

### BRIEF DESCRIPTION OF THE DRAWINGS

Further detailed description of the present application is provided below with reference to the accompanying drawings and embodiments.

FIG. 1 is a schematic structural diagram of the compatible display mechanism according to an embodiment of the present application.

FIG. 2 is an enlarged partial view of portion A in FIG. 1.

FIG. 3 is a partial exploded structural diagram of the compatible display mechanism according to an embodiment of the present application.

FIG. 4 is a structural diagram of the corner support block of the compatible display mechanism according to an embodiment of the present application.

FIG. 5 is a structural diagram of the status indicator of the compatible display mechanism according to an embodiment of the present application.

FIG. 6 is an exploded structural diagram of the display mechanism according to an embodiment of the present application.

FIG. 7 is a sectional view of the latching member mounted on the box body according to an embodiment of the present application.

FIG. 8 is an enlarged partial view of portion B in FIG. 7.

FIG. 9 is a sectional view of the protection plate mounted on the box body according to an embodiment of the present application.

FIG. 10 is an enlarged partial view of portion C in FIG. 9.

### REFERENCE SIGNS IN THE DRAWINGS ARE AS FOLLOWS

1. Display screen mechanism; 11. Box body; 111. Corner mounting groove; 112. First groove; 113. Second groove; 114. First fastening hole; 115. Frame; 116. First support arm; 117. Second support arm; 118. Latching groove; 12. Display module; 121. Window; 13. Status indicator; 131. Indicator plate; 1311. First indicator part; 1312. Second indicator part; 132. Actuating tab; 14. Battery assembly; 15. Knob; 16. Support frame; 161. Rotating groove; 162. Second fastening hole; 17. Protection plate; 171. Third groove; 172. First protruding hook; 173. Second protruding hook; 18. Latching member; 181. Latching body; 182. Latching hook; 183. First elastic arm; 184. Second elastic arm; 2. Support assembly; 21. Corner support block; 211. Corner block; 212. Side plate; 213. Mounting groove; 3. Support frame.

### DETAILED DESCRIPTION OF DISCLOSED EMBODIMENTS

To make the technical problems, technical solutions and beneficial effects of the present application more clear, the application will be further explained in detail below with reference to the drawings and embodiments. It should be understood that the specific embodiments described here are only used to illustrate the application, rather than to limit the application.

It should be understood that the terms “upper,” “lower,” “left,” “right,” “front,” “rear,” “middle,” and the like, which indicate orientation or positional relationships, are based on the orientations or positional relationships shown in the drawings. These terms are used merely to facilitate the description of the present application and to simplify the description, and are not intended to indicate or imply that the indicated devices or elements must have a particular orientation, be constructed and operated in a particular orientation, and are therefore not to be construed As limiting the present application.

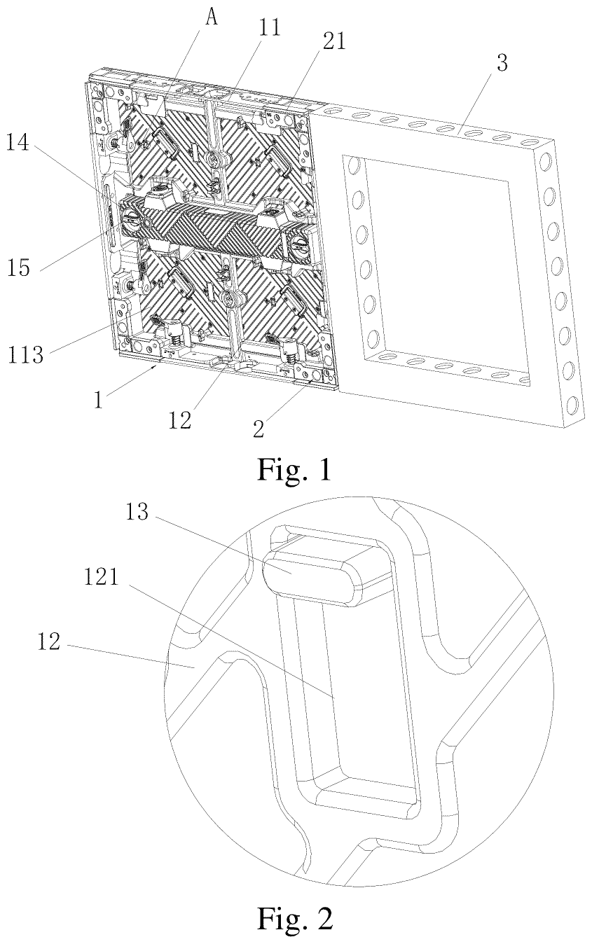

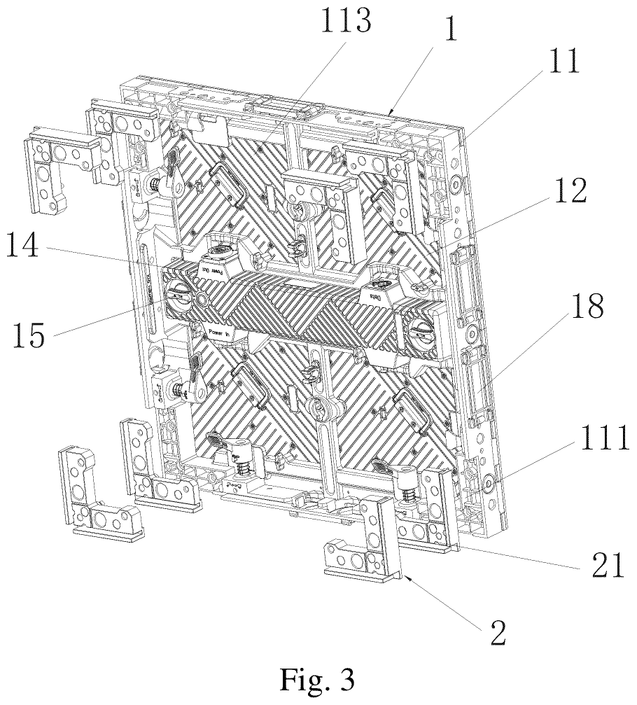

As shown in FIGS. 1, 3, and 4, an embodiment of the present application provides a compatible display mechanism, including a display screen mechanism 1, a support assembly 2, and a support frame 3 connected to a side surface of the display screen mechanism 1. The support assembly 2 includes a plurality of corner support blocks 21 of different thicknesses. It is understood that the display screen mechanism 1 includes, but is not limited to, LED display screens. A plurality of corner support blocks 21 with different thicknesses may be provided as needed according to actual requirements.

A corner mounting groove 111 is provided at a corner of the display screen mechanism 1. The corner support block 21 corresponding to the support frame 3 is mounted in the corner mounting groove 111. The side surface of the support frame 3 abuts against the side surface of the display screen mechanism 1 and the corner support block 21, such that the support frame 3 is adapted to the display screen mechanism 1 and the corner support block 21. It is understood that the corner mounting groove 111 is arranged on the back surface of the box body 11, and the corner mounting grooves 111 are respectively provided at all four corners of the box body 11. In addition, a connection hole for connecting the support frame 3 is also provided at a corner of the box body 11.

In this application, the support assembly 2 includes a plurality of corner support blocks 21 with different thicknesses. A corner mounting groove 111 is provided at each corner of the display screen mechanism 1, and the corner support block 21 corresponding to the support frame 3 is mounted in the corner mounting groove 111. When the display screen mechanism 1 or the support frame 3 needs to be replaced, a corner support block 21 of appropriate thickness can be selected based on the thicknesses of the support frame 3 and the display screen mechanism 1. This ensures that when the support frame 3 is mounted to the side surface of the display screen mechanism 1, the side surface of the support frame 3 abuts against the side surface of the display screen mechanism 1 and the corner support block 21. In this application, corner support blocks 21 of varying thicknesses can be selected according to the thickness of the display screen mechanism 1 and/or the support frame 3. This ensures that the thickness of the side surface of the support frame 3 equals the sum of the thickness of the side surface at the corner of the box body 11 and the thickness of the corner support block 21, thereby ensuring the stable mounting of the display screen mechanism 1 onto the support frame 3. Moreover, it is not necessary to replace both the display screen mechanism 1 and the support frame 3 simultaneously. By simply selecting a corner support block 21 with a matching thickness, the display screen mechanism 1 can be stably mounted onto the support frame 3, thereby reducing the replacement cost and simplifying the replacement operation of the compatible display mechanism.

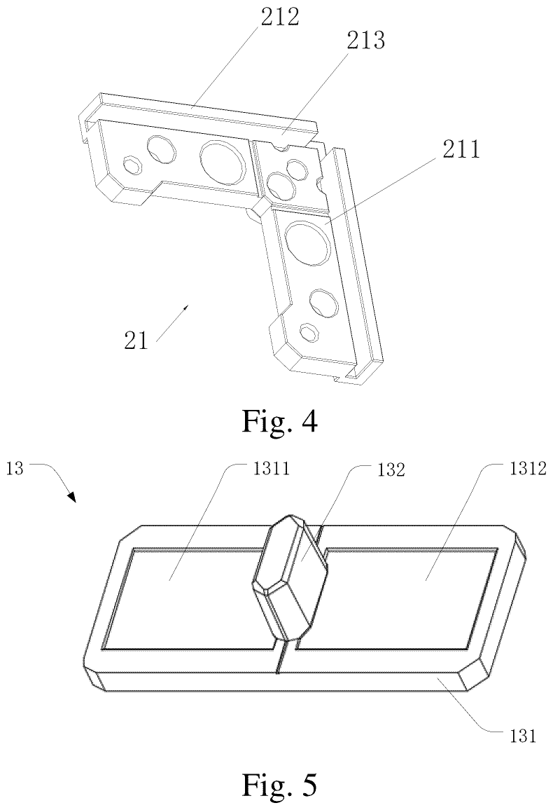

In one embodiment, as shown in FIGS. 1 and 4, the corner support block 21 includes a corner block 211 and two side plates 212 both connected to the corner block 211. A mounting groove 213 is provided between each side plate 212 and the corner block 211. It is understood that the two side plates 212 are perpendicular to each other, and the side plates 212 and the corner block 211 are integrally formed.

The corner block 211 is installed in the corner mounting groove 111, with the two side plates 212 respectively aligned with two adjacent side edges of the display screen mechanism 1. The side surface of the support frame 3 abuts against the side surface of the display screen mechanism 1 and the side plate 212. In this embodiment, the edge of the advertising curtain can be stored in the mounting groove 213, allowing the corner support block 21 to also function as a support for the advertising curtain.

In one embodiment, as shown in FIGS. 1 and 2, the display screen mechanism 1 includes a box body 11 and multiple display modules 12 mounted on the box body 11. The corner mounting groove 111 is provided at the corner on the end of the box body 11 away from the display modules 12. It is understood that the display modules 12 are installed on the front side of the box body 11.

The corner support block 21 corresponding to the support frame 3 is installed in the corner mounting groove 111. The side surface of the support frame 3 abuts against the side surface of the box body 11 and the corner support block 21, so that the support frame 3 is adapted to the box body 11 and the corner support block 21.

The display screen mechanism 1 further includes multiple status indicators 13 installed in a one-to-one correspondence with the display modules 12. It is understood that the status indicators 13 can indicate whether the corresponding display module 12 is damaged or functioning properly.

In this embodiment, after the display module 12 is removed from the box body 11, the status indicator 13 indicates whether the corresponding display module 12 is in a damaged or normal state. The status indicator 13 helps prevent maintenance personnel from confusing functional and faulty display modules 12, thereby ensuring ease of maintenance.

In one embodiment, as shown in FIGS. 1, 2, and 5, the status indicator 13 includes an indicator plate 131 and an actuating tab 132 connected to the indicator plate 131. The indicator plate 131 is provided with a first indicator part 1311 and a second indicator part 1312 located on opposite sides of the actuating tab 132. It is understood that the actuating tab 132 and the indicator plate 131 are integrally formed. The first indicator part 1311 and the second indicator part 1312 may indicate the state (functional or faulty) of the display module 12 through different colors, texts, or patterns.

The display module 12 is provided with an internal space (not shown) and a window 121 that communicates with the internal space. The indicator plate 131 is slidably mounted within the internal space, and one end of the actuating tab 132, opposite the indicator plate 131, extends outward through the window 121. It can be understood that the window 121 is arranged on the back side of the display module 12.

The actuating tab 132 is used to drive the indicator plate 131 to slide in the internal space, such that the window 121 displays either the first indicator part 1311 or the second indicator part 1312.

In this embodiment, the maintenance personnel can slide the indicator plate 131 in the internal space by actuating the actuating tab 132. When the first indicator part 1311 is positioned at the window 121, the second indicator part 1312 is hidden in the internal space, allowing the maintenance personnel to view the first indicator part 1311 through the window 121. Conversely, when the second indicator part 1312 is positioned at the window 121, the first indicator part 1311 is hidden in the internal space, and the second indicator part 1312 becomes visible through the window 121. The first indicator part 1311 and the second indicator part 1312 indicate whether the display module 12 is in a proper or damaged state. The desired indicator—either the first indicator part 1311 or the second indicator part 1312—can be displayed through the window 121 simply by toggling the actuating tab 132, making the status indicator 13 easy to operate and facilitating inspection of the display module 12 by maintenance personnel.

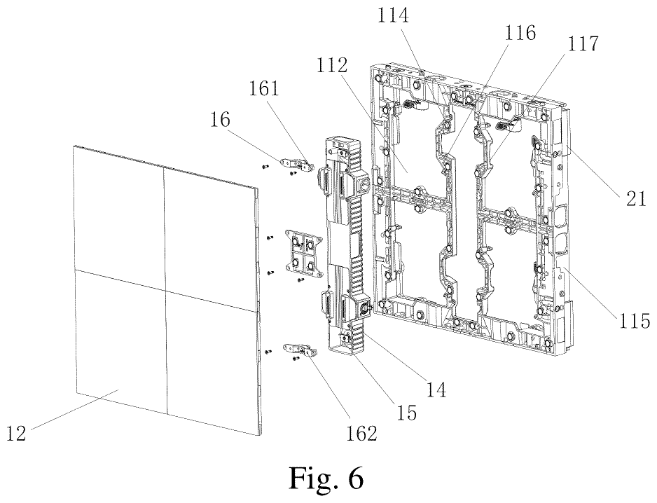

In one embodiment, as shown in FIGS. 1 and 6, opposite ends of the box body 11 are respectively provided with a first groove 112 and a second groove 113 in communication with the first groove 112. The display module 12 is configured to cover the first groove 112, and the corner mounting groove 111 is provided at a corner of the second groove 113. It can be understood that the first groove 112 is provided on the front side of the box body 11, while the second groove 113 is provided on the back side of the box body 11.

The display screen mechanism 1 further includes a battery assembly 14, a knob 15 provided with a rotating latch, and a support frame 16 provided with a rotating groove 161. The knob 15 is rotatably mounted on the battery assembly 14. The support frame 16 is mounted on the box body 11 and located in the second groove 113. The battery assembly 14 is installed in the second groove 113 by the rotating latch locked into the rotating groove 161. It can be understood that the battery assembly 14 is mounted in the second groove 113 and electrically connected to the display module 12, so that the battery assembly 14 can supply power to the display module 12.

Specifically, by rotating the knob 15, the rotating latch can be locked into or released from the rotating groove 161, thereby enabling the attachment or detachment of the battery assembly 14 from the box body 11. In this embodiment, the battery assembly 14 can be easily attached to or detached from the box body 11, simplifying the assembly and disassembly process.

In one embodiment, as shown in FIG. 6, the box body 11 is further provided with a first fastening hole 114 that communicates with the first groove 112, and the support frame 16 is provided with a second fastening hole 162; the support frame 16 is mounted on the box body 11 by the fastening member inserted into the first fastening hole 114 and the second fastening hole 162. It is understood that the fastening members include but are not limited to screws, bolts, and the like.

Specifically, maintenance personnel can remove the battery assembly 14 from the support frame 16 through the knob 15 on the back side of the box body 11, allowing the battery assembly 14 to be taken out from the second groove 113. The display module 12 can be removed from the front side of the box body 11. Then, by uninstalling the fastening members from the first fastening hole 114 and the second fastening hole 162, the support frame 16 separates from the box body 11, enabling the battery assembly 14 to be removed together with the support frame 16 from one side of the first groove 112. This compatible display mechanism allows the battery assembly 14 to be removed from both the front and back sides of the box body 11, making the installation and removal of the battery assembly 14 simple and convenient.

In one embodiment, as shown in FIG. 6, the box body 11 includes a frame 115 and a first support arm 116 and a second support arm 117 spaced apart and connected to the frame 115. The first groove 112 and the second groove 113 are respectively provided at opposite ends of the frame 115. Both the first support arm 116 and the second support arm 117 are provided with the first fastening hole 114. The battery assembly 14 is installed on the first support arm 116 and the second support arm 117 via the support frame 16. It is to be understood that the first support arm 116, the second support arm 117, and the frame 115 are integrally formed, and both the first support arm 116 and the second support arm 117 are located inside the frame 115. In this embodiment, the first support arm 116 and the second support arm 117 serve to support the battery assembly 14, thereby further enhancing the stability of the battery assembly 14 when installed on the box body 11.

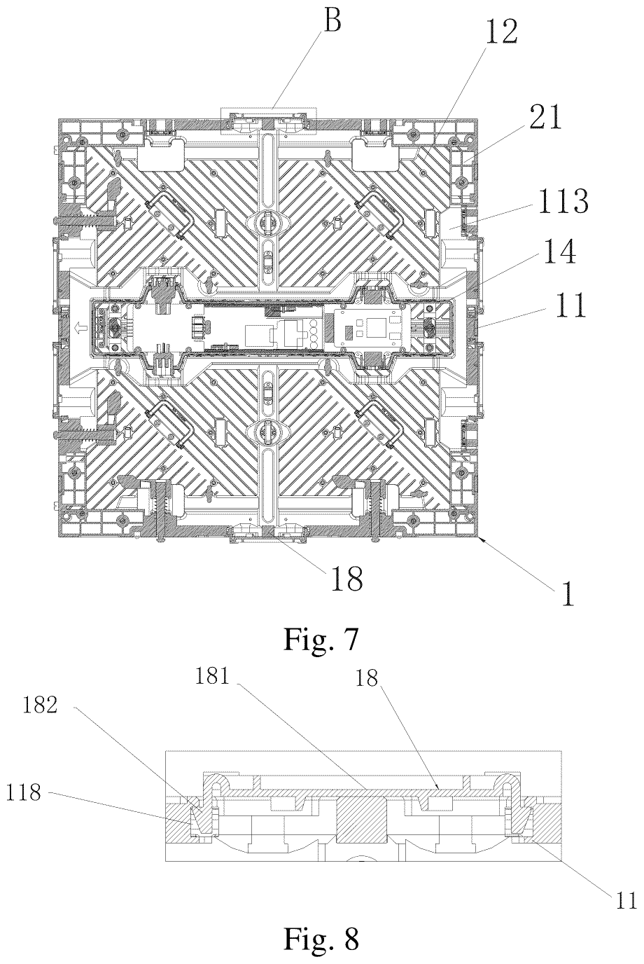

In one embodiment, as shown in FIGS. 7 to 10, the display screen mechanism 1 further includes a protection plate 17 and a latching member 18. The protection plate 17 is detachably mounted on the side surface of the box body 11 via the latching member 18. It is understood that when a side surface of the box body 11 is not connected to the support frame 3, the protection plate 17 can be installed on that side surface through the latching member 18. In this embodiment, the protection plate 17 is installed on the exposed side surface of the box body 11. The protection plate 17 serves to protect the side surface of the box body 11, thereby extending the service life of the compatible display mechanism. Additionally, the protection plate 17 can feature different patterns and be designed in various shapes, enhancing the aesthetic appeal of the compatible display mechanism. Moreover, the protection plate 17 is mounted on the side surface of the box body 11 via the latching member 18, making the assembly and disassembly between the protection plate 17 and the box body 11 simple and convenient.

In one embodiment, as shown in FIGS. 7 and 8, the latching member 18 includes a latching body 181 and a latching hook 182 connected to the latching body 181. A latching groove 118 adapted to the latching hook 182 is provided on the side surface of the box body 11. The protection plate 17 is provided with a third groove 171 adapted to the latching body 181. It is understood that the latching body 181 and the latching hook 182 are integrally formed.

The latching body 181 is installed on the box body 11 by the latching hook 182 engaged in the latching groove 118. The protection plate 17 is installed on the side surface of the box body 11 by the latching body 181 inserted in the third groove 171. It is understood that the latching members 18 are installed on all four sides of the box body 11.

In this embodiment, the latching body 181 is installed on the box body 11 by the latching hook 182 engaged in the latching groove 118. The protection plate 17 is mounted on the side surface of the box body 11 by the latching body 181 inserted in the third groove 171. The assembly and disassembly operations between the latching member 18 and the box body 11, as well as between the protection plate 17 and the latching member 18, are simple.

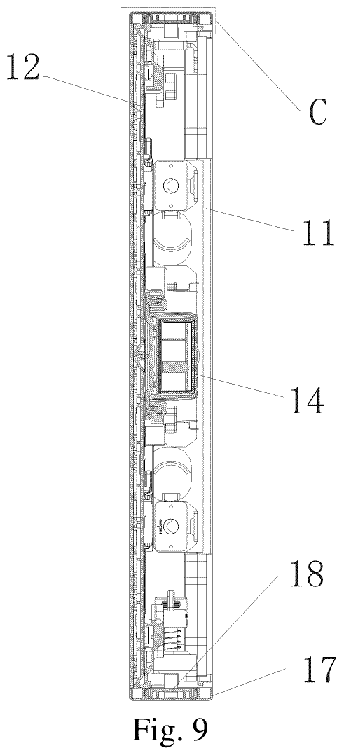

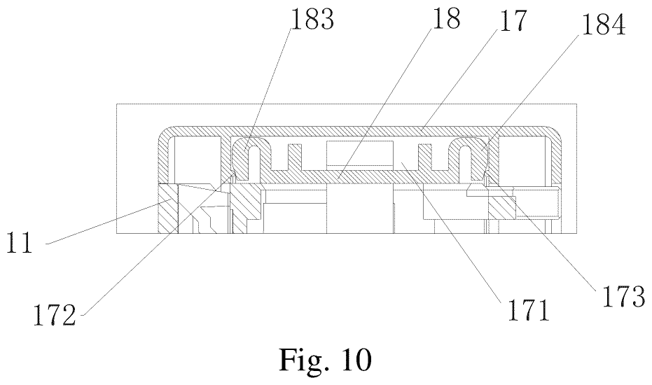

In one embodiment, as shown in FIGS. 9 and 10, the latching member 18 further includes a first elastic arm 183 and a second elastic arm 184 connected to opposite sides of the latching body 181, and the opposite inner sidewalls of the third groove 171 are respectively provided with a first protruding hook 172 and a second protruding hook 173. It can be understood that the first elastic arm 183, the second elastic arm 184, the latching body 181, and the latching hook 182 are integrally formed; the first protruding hook 172 and the second protruding hook 173 both protrude toward the center of the third groove 171.

When the latching body 181 is inserted into the third groove 171, the first protruding hook 172 abuts against the first elastic arm 183, and the second protruding hook 173 abuts against the second elastic arm 184.

Specifically, during the insertion of the latching body 181 into the third groove 171, the opposite sidewalls of the third groove 171 respectively compress the first elastic arm 183 and the second elastic arm 184. Meanwhile, the first protruding hook 172 presses tightly against the first elastic arm 183, and the second protruding hook 173 presses tightly against the second elastic arm 184. As a result, the first elastic arm 183 and the second elastic arm 184 are interference-fitted into the third groove 171, ensuring the stability of the protection plate 17 installed on the latching member 18.

The above are merely the preferred embodiments of the compatible display mechanism of this application, and are not intended to limit the scope of the application. Any modification, equivalent substitution and improvement made within the spirit and principle of this application shall be included in the protection scope of this application.

What is claimed is:

1. A compatible display mechanism, comprising:
a display screen mechanism, a support assembly, and a support frame connected to a side surface of the display screen mechanism; the support assembly comprises a plurality of corner support blocks having different thicknesses; and
a corner mounting groove is provided at a corner of the display screen mechanism, and the corner support block corresponding to the support frame is mounted in the corner mounting groove; a side surface of the support frame abuts against the side surface of the display screen mechanism and the corner support block, such that the support frame is adapted to the display screen mechanism and the corner support block.

2. The compatible display mechanism of claim 1, wherein:
the corner support block comprises a corner block and two side plates each connected to the corner block, and a mounting groove is provided between each side plate and the corner block; and
the corner block is mounted in the corner mounting groove, the two side plates are respectively aligned with two adjacent side edges of the display screen mechanism, and the side surface of the support frame abuts against the side surface of the display screen mechanism and the side plates.

3. The compatible display mechanism of claim 1, wherein:
the display screen mechanism comprises a box body and a plurality of display modules mounted on the box body, and the corner mounting groove is arranged at a corner of the box body on an end away from the display module;
the corner support block corresponding to the support frame is mounted in the corner mounting groove, and the side surface of the support frame abuts against a side surface of the box body and the corner support block, such that the support frame is adapted to the box body and the corner support block; and
the display screen mechanism further comprises a plurality of status indicators mounted on the display modules in a one-to-one correspondence.

4. The compatible display mechanism of claim 3, wherein:
the status indicator comprises an indicator plate and an actuating tab connected to the indicator plate, and the indicator plate is provided with a first indicator part and a second indicator part located on opposite sides of the actuating tab;
the display module is provided with an internal space and a window communicating with the internal space, the indicator plate is slidably mounted in the internal space, and an end of the actuating tab away from the indicator plate protrudes from the window; and
the actuating tab is configured to drive the indicator plate to slide in the internal space, such that the window displays the first indicator part or the second indicator part.

5. The compatible display mechanism of claim 3, wherein:
opposite ends of the box body are respectively provided with a first groove and a second groove in communication with the first groove, the display module is configured to cover the first groove, and the corner mounting groove is arranged at a corner of the second groove;
the display screen mechanism further comprises a battery assembly, a knob provided with a rotating latch, and a support frame provided with a rotating groove; the knob is rotatably mounted on the battery assembly, the support frame is mounted on the box body and located in the second groove, and the battery assembly is mounted in the second groove by the rotating latch locked into the rotating groove.

6. The compatible display mechanism of claim 5, wherein:
the box body is further provided with a first fastening hole in communication with the first groove, and the support frame is provided with a second fastening hole; and
the support frame is mounted on the box body by a fastener inserted into the first fastening hole and the second fastening hole.

7. The compatible display mechanism of claim 6, wherein:
the box body comprises a frame and a first support arm and a second support arm spaced apart and connected to the frame, the first groove and the second groove are respectively arranged at opposite ends of the frame; and
the first support arm and the second support arm each are provided with the first fastening hole; the battery assembly is mounted on the first support arm and the second support arm by the support frame.

8. The compatible display mechanism of claim 3, wherein:
the display screen mechanism further comprises a protection plate and a latching member, and the protection plate is detachably mounted on the side surface of the box body by the latching member.

9. The compatible display mechanism of claim 8, wherein:
the latching member comprises a latching body and a latching hook connected to the latching body, a side of the box body is provided with a latching groove adapted to the latching hook, and the protection plate is provided with a third groove adapted to the latching body; and
the latching body is mounted on the box body by the latching hook engaged in the latching groove, and the protection plate is mounted on the side surface of the box body by the latching body inserted into the third groove.

10. The compatible display mechanism of claim 9, wherein;
the latching member further comprises a first elastic arm and a second elastic arm connected to opposite sides of the latching body, and opposite inner sidewalls of the third groove are respectively provided with a first protruding hook and a second protruding hook; and
when the latching body is inserted into the third groove, the first protruding hook abuts against the first elastic arm, and the second protruding hook abuts against the second elastic arm.
